(19) United States
(12) Patent Application Publication
(10) Pub. No.: US 2026/0253642 A1
(43) Pub. Date: Aug. 27, 2026

(54) NAND FLASH MEMORY DEVICE CAPABLE OF SELECTIVELY ERASING FLASH MEMORY CELL

(71) Applicants: SK hynix Inc., Icheon-si (KR); Seoul National University R&DB Foundation, Seoul (KR)

(72) Inventor: Sung Ho Park, Seoul (KR)

(21) Appl. No.: 19/446,564

(22) Filed: Jan. 12, 2026

(30) Foreign Application Priority Data
Feb. 27, 2025 (KR) 10-2025-0026047

(51) Int. Cl. G11C 16/14; G11C 16/04; G11C 16/24

(52) U.S. Cl. CPC G11C 16/14; G11C 16/0483; G11C 16/24

(57) ABSTRACT

A memory device includes a cell array including a NAND string comprising a plurality of memory cells whose control gates are connected to a plurality of word lines, and a plurality of drain selection switches connected between the plurality of memory cells and a bit line and controlled by a plurality of drain selection lines; and a control circuit configured to control a erase operation for erasing a selected memory cell. During the first erase operation, the control circuit sets a voltage applied to the first bit line and a voltage applied to a first one of the plurality of first drain selection lines so as to generate GIDL current at a first one of the plurality of first drain selection switches, and sets voltage applied to another one of the drain selection lines to be lower than the voltage of the first one of the drain selection lines.

### CROSS-REFERENCE TO RELATED APPLICATION

The present application claims priority to Korean Patent Application No. 10-2025-0026047, filed on February 27, 2025, which is incorporated herein by reference in its entirety.

### BACKGROUND

### 1. Technical Field

Embodiments relate to a NAND flash memory device capable of erasing data stored in a selected flash memory cell among a plurality of flash memory cells included in a NAND string.

### 2. Related Art

In conventional three-dimensional (3D) NAND flash memory devices, an erase method utilizing gate-induced drain leakage (GIDL) current has been used.

In particular, a technique for preventing unintended erase of other flash memory cells while performing an erase operation for a selected flash memory cell in a NAND flash memory device.

However, an improved technique capable of further stabilizing erase performance of a selected flash memory cell is desired in three-dimensional (3D) NAND flash memory devices.

### SUMMARY

In accordance with an embodiment of the present disclosure, a flash memory device may include a cell array including a first NAND string comprising a plurality of first flash memory cells whose control gates are connected to a plurality of word lines, and a plurality of first drain selection switches connected between the plurality of first flash memory cells and a first bit line and controlled by a plurality of first drain selection lines; and a control circuit configured to control a first erase operation for erasing a selected first flash memory cell among the plurality of first flash memory cells, wherein, during the first erase operation, the control circuit sets a voltage applied to the first bit line and a voltage applied to a first one of the plurality of first drain selection lines so as to generate GIDL current at a first one of the plurality of first drain selection switches; and wherein, during the first erase operation, the control circuit sets voltages applied to another one of the first drain selection lines, other than the first one of the plurality of first drain selection lines, the voltage lower than the voltage applied to the first one of the plurality of first drain selection lines, and wherein the first one of the plurality of first drain selection switches is connected to the first bit line, and the first one of the plurality of first drain selection lines controls the first one of the plurality of first drain selection switches.

### BRIEF DESCRIPTION OF THE DRAWINGS

The accompanying figures, where like reference numerals refer to identical or functionally similar elements throughout the separate views, together with the detailed description below, serve to further illustrate embodiments that include various features, and explain various principles and beneficial aspects of those embodiments.

FIG. 1 is a block diagram illustrating a flash memory device according to an embodiment of the present disclosure.

FIG. 2 is a circuit diagram illustrating erase operation conditions of a flash memory device according to an embodiment of the present disclosure.

FIG. 3 is a table illustrating voltage conditions applied to various lines during an erase operation of a flash memory device according to an embodiment of the present disclosure.

FIGS. 4, 5, and 6 are graphs illustrating erase inhibition performance and erase improvement performance according to embodiments of the present disclosure.

### DETAILED DESCRIPTION

Various embodiments will be described below with reference to the accompanying figures. Embodiments are provided for illustrative purposes and other embodiments that are not explicitly illustrated or described are possible. Further, modifications can be made to embodiments of the present disclosure that will be described below in detail.

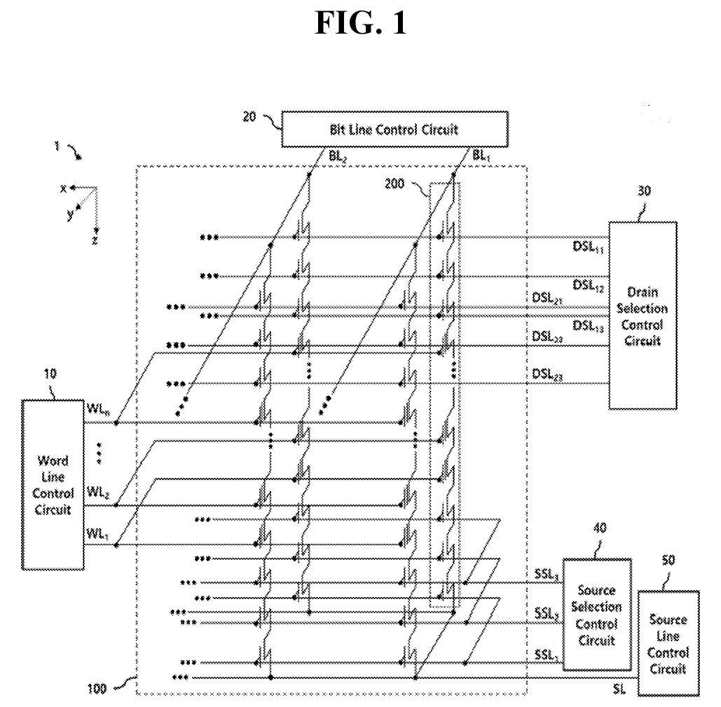

FIG. 1 is a block diagram illustrating a flash memory device 1 according to an embodiment of the present disclosure.

The flash memory device 1 includes a cell array 100 having a plurality of NAND strings 200, a word line control circuit 10 configured to control word lines WL of the cell array 100, a bit line control circuit 20 configured to control bit lines BL of the cell array 100, a drain selection control circuit 30 configured to control drain selection lines DSL of the cell array 100, a source selection control circuit 40 configured to control source selection lines SSL of the cell array 100, and a source line control circuit 50 configured to control source lines SL of the cell array 100.

The word line control circuit 10, the bit line control circuit 20, the drain selection control circuit 30, the source selection control circuit 40, the source selection control circuit 40, and the source line control circuit 50 may be collectively referred to as a control circuit.

In this embodiment, the control circuit controls the word lines, bit lines, drain selection lines, source selection lines, and source lines to perform a selective erase operation for a single flash memory cell.

The cell array 100 is configured such that a plurality of NAND strings are arranged in two dimensions, resulting in a three-dimensional arrangement of a plurality of flash memory cells.

Each word line WL is commonly connected to the control gates of a plurality of flash memory cells located on a plane perpendicular to the z-axis. Each bit line BL is commonly connected to the drains of the drain selection switches of a plurality of NAND strings 200 located on a plane perpendicular to the x-axis. Each drain selection line DSL is commonly connected to the gates of the drain selection switches of a plurality of NAND strings 200 located on a plane perpendicular to the y-axis.

For example, a source line SL is commonly connected to the sources of source selection switches SS of all NAND strings 200.

For example, a source selection line SSL is commonly connected to the gates of the source selection switches of all NAND strings 200.

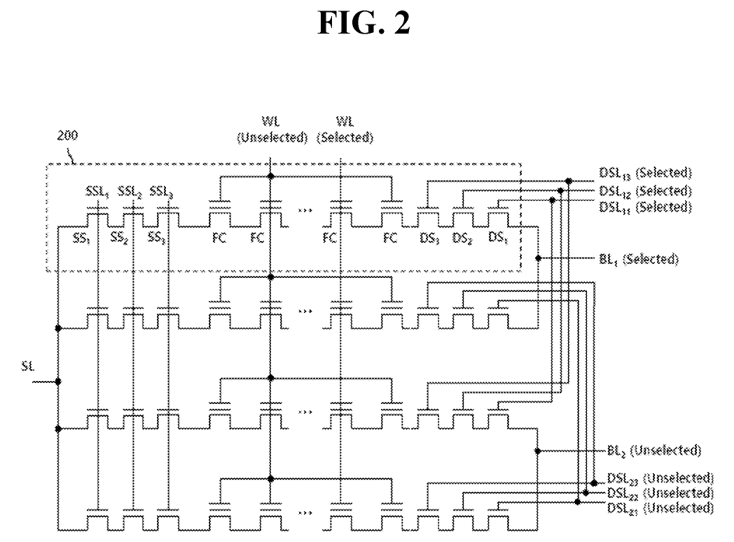

FIG. 2 illustrates four NAND strings 200 connected to two adjacent bit lines and two adjacent drain selection lines in FIG. 1.

Each NAND string 200 includes, as conventionally known, a plurality of flash memory cells FC connected in series between a bit line BL and a source line SL.

In the embodiment of FIG. 2, each NAND string 200 includes a plurality of drain selection switches DS₁, DS₂, and DS₃ connected in series between the bit line BL and the plurality of flash memory cells FC, and a plurality of source selection switches SS₁, SS₂, and SS₃ connected in series between the plurality of flash memory cells FC and the source line SL.

The control gates of the flash memory cells FC are connected to a plurality of word lines WL.

The gates of the drain selection switches DS₁ to DS₃ are connected to a plurality of drain selection lines DSL₁ to DSL₃.

The gates of the source selection switches SS₁ to SS₃ are connected to a plurality of source selection lines SSL₁ to SSL₃.

For simplicity, the plurality of drain selection switches included in a single NAND string 200 may be collectively referred to as DS, and the plurality of source selection switches may be collectively referred to as SS.

Likewise, the plurality of drain selection lines connected to a single NAND string 200 may be collectively denoted as DSL, and the plurality of source selection lines may be collectively denoted as SSL.

In this embodiment, each of the numbers of drain selection switches and source selection switches included in a single NAND string is three. However, embodiments of the present disclosure are not limited thereto.

A drain selection line DSLₙⱼ may be referred to as a j-th drain selection line, and a source selection line SSLₙⱼ may be referred to as a j-th source selection line, where j is 1,2, or 3.

A drain selection switch connected to the j-th drain selection line may be referred to as a j-th drain select switch DSⱼ.

The first drain selection line DSLₙ₁ may be referred to as the outermost drain selection line, and the first source selection line SSL₁ may be referred to as the outermost source selection line.

Here, n corresponds to a position of each NAND string along the y-axis in FIG. 1, and multiple drain selection lines having a common n value may be referred to as an n-th drain selection line group.

In the embodiment of FIG. 2, the drain selection switches DS and source selection switches SS are NMOS transistors, and the regions connected to the bit line BL and the source line SL are doped with n-type impurities.

When the drain selection switches DS and source selection switches SS are replaced with other types of semiconductor switches such as PMOS transistors, the voltages applied to the bit line BL, source line SL, drain selection lines DSL, and source selection lines SSL during an erase operation may be correspondingly modified. Such modifications can be implemented by one of ordinary skill in the art based on teachings of the present disclosure, and therefore detailed descriptions thereof will be omitted for the interest of brevity.

Embodiments of the present invention relate to a technique for selecting and erasing a single flash memory cell within the cell array 100 while improving both the erase performance of the selected flash memory cell and the erase-inhibition performance of the unselected flash memory cells.

The word line control circuit 10 provides different voltage signals to a word line connected to the selected flash memory cell and to word lines connected to unselected flash memory cells.

In this embodiment, the bit line control circuit 20, the drain selection control circuit 30, the source selection control circuit 40, and the source line control circuit 50 set the voltages of the bit lines BL, the drain selection lines DSL, the source line(s) SL, and the source selection lines SSL to specific conditions so as to generate gate-induced drain leakage (GIDL) current in the NAND string 200 where the selected flash memory cell FC is located.

Holes generated by the GIDL current are supplied to the channel of the NAND string 200. The electrons stored in a charge-storage layer of the flash memory cell FC move into the channel (or the holes themselves are stored in the charge-storage layer), thereby lowering the threshold voltage of the flash memory cell FC and performing an erase operation.

In embodiments of the present disclosure, each NAND string 200 includes a plurality of drain selection switches and a plurality of source selection switches, that are respectively connected to a plurality of drain selection lines and a plurality of source selection lines, rather than a single drain selection switch and a single source selection switch that are respectively connected to a single drain selection line and a single source selection line.

A word line connected to the selected flash memory cell is referred to as a selected word line, and a word line not connected to the selected flash memory cell is referred to as an unselected word line.

Similarly, a bit line and a drain selection line connected to a NAND string including the selected flash memory cell are referred to as a selected bit line and a selected drain selection line, respectively, and bit lines and drain selection lines connected to NAND strings not including the selected flash memory cell are referred to as unselected bit lines and unselected drain selection lines, respectively.

For example, unlike the bit lines and drain selection lines, the source selection lines are commonly connected to all NAND strings.

Accordingly, in embodiments of the present disclosure, when an erasing operation is performed on a specific single memory cell, a GIDL current generated from one or more the drain selection switches is used, while the source selection switches do not generate such GIDL current.

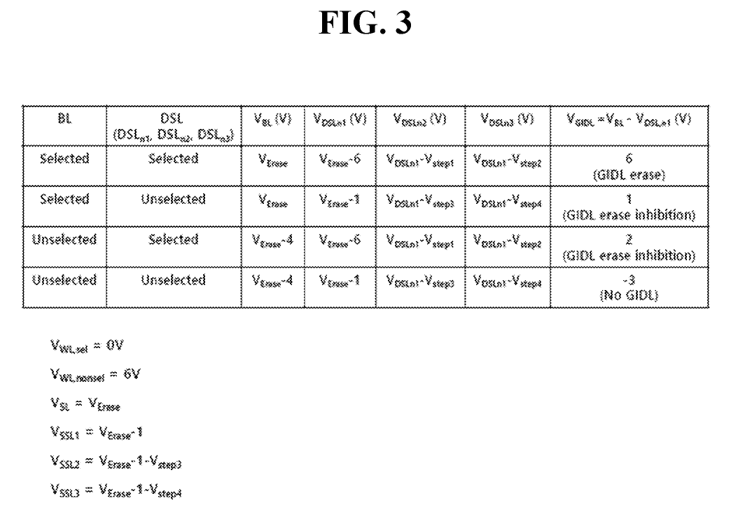

FIG. 2 is a circuit diagram illustrating an erase operation for a single flash memory cell in the flash memory device 1 according to an embodiment of the present disclosure. FIG. 3 is a table showing voltage conditions applied to various lines during an erase operation according to an embodiment of the present disclosure.

The table of FIG. 3 shows voltage conditions of the bit line, a plurality of drain selection lines, and a plurality of source selection lines with reference to an erase voltage V_{Erase}.

The erase voltage V_{Erase} corresponds to the bit line voltage VBL applied to the selected bit line.

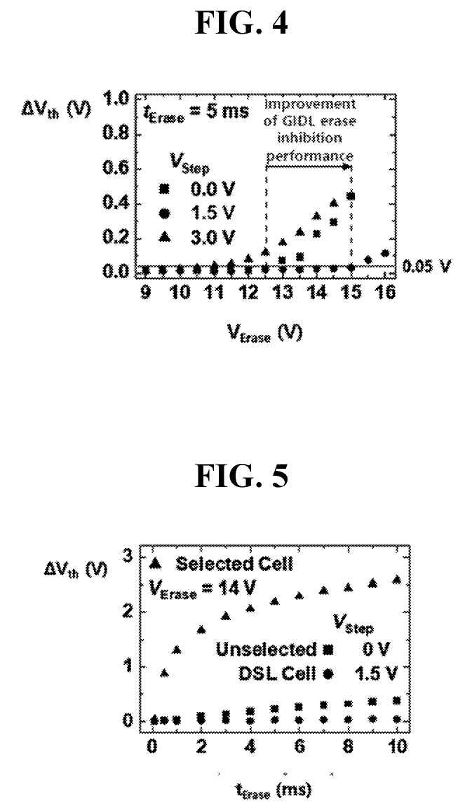

The erase voltage V_{Erase} may be selected within a predetermined range, which will be described in detail below with reference to FIG. 4.

In this embodiment, a voltage 4 V lower than the erase voltage V_{Erase} is applied to the unselected bit lines.

The selected outermost drain selection line DSLₙ₁ is applied with a voltage 6 V lower than the erase voltage V_{Erase}, and the unselected outermost drain selection line DSLₙ₁ is applied with a voltage 1 V lower than the erase voltage V_{Erase}.

To improve the erase performance of the selected flash memory cell and enhance the erase inhibition performance of the unselected flash memory cells, the drain selection lines other than the outermost drain selection line DSLₙ₁ are applied with voltages lower than the voltage VDSLₙ₁ applied to the outermost drain selection line.

Specifically, the selected second and third drain selection lines DSLₙ₂ and DSLₙ₃ are applied with voltages V_{DSLn1} − Vₛₜₑₚ₁ and V_{DSLn1} − Vₛₜₑₚ₂, respectively, where Vₛₜₑₚ₁ and Vₛₜₑₚ₂ have positive values satisfying Vₛₜₑₚ₁ ≤ Vₛₜₑₚ₂.

The unselected second and third drain selection lines DSLₙ₂ and DSLₙ₃ are applied with voltages V_{DSLn1} − Vₛₜₑₚ₃ and V_{DSLn1}− Vₛₜₑₚ₄, respectively, where Vₛₜₑₚ₃ and Vₛₜₑₚ₄ have positive values satisfying Vₛₜₑₚ₃ ≤ Vₛₜₑₚ₄.

GIDL voltage V_{GIDL} is defined as the voltage difference between the bit line voltage V_{BL} and the outermost drain selection line voltage V_{DSLn1}.

When both the bit line and the drain selection line are selected, the GIDL voltage is 6 V, and a GIDL current is generated to perform the erase operation on the selected flash memory cell.

When both the bit line and the drain selection line are unselected, the GIDL voltage is −3 V, and no GIDL current is generated, thereby preventing any erase operation.

When the bit line is selected and the drain selection lines are unselected, the GIDL voltage is 1 V, and when the drain selection lines are selected and the bit line is unselected, the GIDL voltage is 2 V. In these cases, a relatively small amount of GIDL current may be generated, but the erase of unselected flash memory cells is effectively inhibited.

In this embodiment, the source line voltage V_{SL} is fixed to the erase voltage V_{Erase}, which corresponds to the voltage of the selected bit line.

The voltages applied to the plurality of source selection lines are fixed to be equal to those of the unselected drain selection lines.

Specifically, the voltage V_{SSL1}of the first source selection line is fixed to the voltage V_{DSLn1} of the unselected first drain selection line, which corresponds to V_{Erase} − 1, the voltage V_{SSL2} of the second source selection line is fixed to the voltage V_{DSLn2} of the unselected second drain selection line, which corresponds to V_{DSLn1} − Vₛₜₑₚ₃, and the voltage V_{SSL3} of the third source selection line is fixed to the voltage V_{DSLn3} of the unselected third drain selection line, which corresponds to V_{DSLn1} − Vₛₜₑₚ₄.

Accordingly, in this embodiment, GIDL current is generated only in the direction of the selected bit line BL1, and no GIDL current is generated in the direction of the source line SL.

In the embodiment of FIG. 3, the voltage V_{WL,sel} of the selected word line is 0 V, while the voltage V_{WL,nonsel} of the unselected word lines is 6 V.

For example, GIDL current is generated on the selected bit-line side and thus flows from the selected bit line BL1 toward the selected memory cell FC. As a result, holes move into the charge-storage layer of the selected flash memory cell FC (or electrons move from the charge-storage layer to the channel), thereby lowering the threshold voltage of the selected flash memory cell.

When a lower voltage, for example, a negative voltage, is applied to the selected word line, holes can move into the charge-storage layer in a shorter time compared to when a zero voltage is applied to the selected word line.

The selective erase operation for only the selected flash memory cell FC reduces current flowing between the bit line BL and the source line SL, thereby reducing power consumption. In other words, during an erase operation on the selected flash memory cell FC, no GIDL current is generated on the source line side, and thus no GIDL current flows from the source line SL toward the selected memory cell FC, thereby keeping power consumption relatively small.

In FIG. 2, the drain selection line corresponding to n = 1 is selected, while the drain selection line corresponding to n = 2 is unselected.

In this embodiment, voltages lower than that of the unselected first drain selection line DSL₂₁ are applied to the unselected second and third drain selection lines DSL₂₂ and DSL₂₃, respectively. This configuration further enhances the erase inhibition performance for the unselected flash memory cells.

When the voltage of the drain selection line decreases, the potential of the silicon channel at the corresponding drain selection switch also decreases, and similarly, the potentials of the silicon channels corresponding to the plurality of flash memory cells included in the NAND string sequentially decrease.

Accordingly, even if GIDL current is generated in the selected NAND string, the channel voltage of the unselected flash memory cells becomes lower than that of conventional devices, thereby weakening the electric field from the channel toward the gate in the unselected flash memory cells.

Consequently, the likelihood of the unselected flash memory cells being erased by the GIDL current according to embodiments of the present disclosure is further reduced compared to conventional devices.

In addition, in this embodiment, voltages lower than that applied to the selected first drain selection line DSL₁₁ are applied to the selected second and third drain selection lines DSL₁₂ and DSL₁₃, respectively, to further improve the erase performance of the selected flash memory cell.

In the NAND string connected to the selected bit line, as shown in FIG. 3, the condition for generating GIDL current at the first drain selection switch is satisfied. By lowering the gate voltages applied to the second and third drain selection switches, additional GIDL currents can also be generated at the second and third drain selection switches.

As a result, a relatively large total GIDL current including GIDL currents generated at the first, second, and third drain selection switches is supplied to the selected flash memory cell, thereby enhancing its erase performance.

This effect may also be applied to a block erase operation.

During the block erase operation, GIDL currents may be generated at the plurality of source selection switches, and the entire block can be erased using these currents.

The voltage conditions applied to the source line and the plurality of source selection lines during the block erase operation can be set in the same manner as the voltage conditions applied to the selected bit line and the plurality of selected drain selection lines described above.

For example, the same voltage applied to the selected bit line is applied to the source line, the same voltage applied to the selected first drain selection line is applied to the first source selection line, the same voltage applied to the selected second drain selection line is applied to the second source selection line, and the same voltage applied to the selected third drain selection line is applied to the third source selection line.

Through this configuration, GIDL currents can be provided not only from the first source selection switch but also from the second and third source select switches, thereby improving the erase performance of the block erase operation.

FIGS. 4, 5, and 6 are graphs illustrating erase inhibition performance and erase improvement performance according to embodiments of the present disclosure.

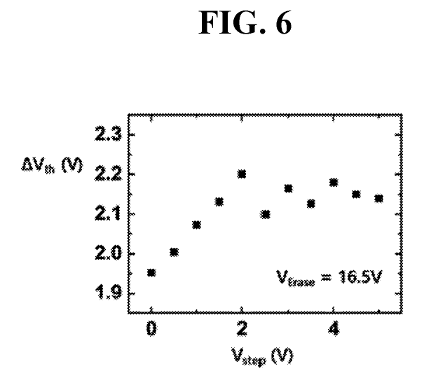

FIGS. 4 and 5 are graphs showing improved erase inhibition performance for unselected flash memory cells, and FIG. 6 is a graph showing improved erase performance for a selected flash memory cell.

FIG. 4 illustrates a relationship between the erase voltage V_{Erase} and the threshold voltage variation ΔVₜₕ of unselected flash memory cells.

As described above, the erase voltage V_{Erase} corresponds to the bit line voltage V_{BL} applied to the selected bit line.

In FIG. 4, Vₛₜₑₚ₃ = Vₛₜₑₚ and Vₛₜₑₚ₄ = 2Vₛₜₑₚ. Hereinafter, Vₛₜₑₚ is referred to as a step voltage.

In FIG. 4, t_{Erase} represents the pulse width during which the erase voltage V_{Erase} is maintained during the erase operation, and is fixed at 5ms.

First, the case where the step voltage Vₛₜₑₚ is 0 V is described.

When the step voltage Vₛₜₑₚ is 0 V in FIG. 4, the same voltage is applied to all drain selection lines.

In FIG. 4, a flash memory cell is regarded as erase-inhibited when the threshold voltage variation ΔVₜₕ is smaller than or equal to 0.05 V.

As shown, as the erase voltage V_{Erase} increases, the threshold voltage variation ΔVₜₕ of the unselected flash memory cell increases.

When the erase voltage V_{Erase} is increased in steps of 0.5 V, the threshold voltage variation ΔVₜₕ is smaller than or equal to 0.05 V at V_{Erase} = 12.5 V, but exceeds 0.05 V at V_{Erase} = 13 V.

Accordingly, when the step voltage Vₛₜₑₚ is 0 V, the maximum erase voltage V_{Erase} is 12.5 V.

In contrast, when the step voltage Vₛₜₑₚ is 1.5 V, the maximum erase voltage V_{Erase} confirmed in the same manner is 15 V.

This indicates that setting the step voltage Vₛₜₑₚ to a positive value of 1.5 V significantly improves the erase inhibition performance of the unselected flash memory cell, compared to when the step voltage Vₛₜₑₚ is 0 V.

However, when the step voltage Vₛₜₑₚ is 3 V, the erase inhibition performance deteriorates.

This is because if the voltages of the drain selection lines, except for the outermost drain selection line, are excessively reduced, GIDL currents may be generated at the corresponding drain selection switches.

Therefore, it is preferable to limit the magnitude of the step voltage within a certain range. Determining the optimal range of the step voltage Vₛₜₑₚ can performed by a person skilled in the art based on teachings of the present disclosure, and therefore detailed descriptions thereof will be omitted for the interest of brevity.

FIG. 5 illustrates a relationship between the erase time t_{Erase}, during which the erase voltage V_{Erase} is applied, and the threshold voltage variation ΔVₜₕ of the flash memory cell.

In FIG. 5, the triangles represent the threshold voltage variation ΔVₜₕ of the selected flash memory cell, the squares represent ΔVₜₕ of the unselected flash memory cell when the step voltage Vₛₜₑₚ is 0 V, and the circles represent ΔVₜₕ of the unselected flash memory cell when the step voltage Vₛₜₑₚ is 1.5 V.

In both selected and unselected flash memory cells, the threshold voltage variation ΔVₜₕ increases as the erase time t_{Erase} increases.

Comparing the cases of step voltages of 0 V and 1.5 V for unselected flash memory cells, ΔVₜₕ is smaller when Vₛₜₑₚ = 1.5 V.

This confirms, as shown in FIG. 4, that setting a nonzero step voltage improves erase inhibition performance.

FIG. 6 illustrates a relationship between the step voltage Vₛₜₑₚ and the threshold voltage variation ΔVₜₕ of the selected flash memory cell.

In FIG. 6, Vₛₜₑₚ₁ = Vₛₜₑₚ and Vₛₜₑₚ₂ = 2Vₛₜₑₚ.

As shown, when the erase voltage V_{Erase} is fixed at 16.5 V and the step voltage Vₛₜₑₚ increases, ΔVₜₕ of the selected flash memory cell increases until Vₛₜₑₚ reaches 2 V, and then remains within a certain range.

Comparing the cases of Vₛₜₑₚ = 0 V and Vₛₜₑₚ = 2 V, ΔVₜₕ of the selected flash memory cell increases by approximately 0.25 V in the latter case, demonstrating improved erase performance.

As described above, one skilled in the art can determine the optimal range of the step voltage Vₛₜₑₚ based the teachings of on the present disclosure, and detailed descriptions thereof will therefore be omitted for the interest of brevity. Specifically, an optimal range of the step voltage Vₛₜₑₚmay be determined by adjusting the step voltage Vₛₜₑₚand identifying the range in which the erase performance on the selected flash memory cell and the erase inhibition performance on unselected flash memory cells improve. For example, when the step voltage Vₛₜₑₚis excessively small, additional GIDL current(s) may not be generated at drain selection switches other than the outermost drain selection switch, resulting in insufficient erase performance on the selected memory cell. In contrast, when the step voltage Vₛₜₑₚis excessively large, GIDL current(s) may be generated at unselected drain selection switches, deteriorating erase inhibition performance on unselected memory cells.

In an embodiment, where a flash memory device comprises a cell array and a control circuit, the cell array including a first NAND string comprising a plurality of first flash memory cells whose control gates are connected to a plurality of word lines, and a plurality of first drain selection switches connected between the plurality of first flash memory cells and a first bit line and controlled by a plurality of first drain selection lines, a method of operating a flash memory device includes: applying, by the control circuit, a voltage to the first bit line and a voltage to a first one the plurality of first drain selection lines connected to a first one of the plurality of first drain selection switches, so as to generate GIDL current at the first one of the plurality of first drain selection switches during a first erase operation, the first erase operation performed on a selected flash memory cell among the plurality of first memory cells; and applying, by the control circuit, a voltage to a second one of the first drain selection lines connected to a second one of the plurality of first drain selection switches during the first erase operation, the voltage applied to the second one of the first drain selection lines being lower than the voltage applied to the first one of the plurality of first drain selection lines. The first one of the plurality of first drain selection switches is located closer to the first bit line than the second one of the plurality of first drain selection switches.

In an embodiment, where the cell array further comprises a second NAND string comprising a plurality of second flash memory cells whose control gates are connected to the plurality of word lines, and a plurality of second drain selection switches connected between the plurality of second flash memory cells and the first bit line and controlled by a plurality of second drain selection lines, the method further includes: applying, by the control circuit, the voltage to the first bit line and a voltage to a first one of the plurality of second drain selection lines connected to a first one of the plurality of second drain selection switches during the first erase operation, so as to avoid generating GIDL current at the first one of the plurality of second drain selection switches; and applying, by the control circuit, a voltage to a second one of the second drain selection lines connected to a second one of the plurality of second drain selection switches during the first erase operation, the voltage applied to the second one of the second drain selection lines being lower than the voltage applied to the first one of the plurality of second drain selection lines. The first one of the plurality of second drain selection switches is located closer to the first bit line than the second one of the plurality of second drain selection switches.

In an embodiment, where the cell array further comprises a third NAND string comprising a plurality of third flash memory cells whose control gates are connected to the plurality of word lines, and a plurality of third drain selection switches connected between the plurality of third flash memory cells and a second bit line and controlled by the plurality of first drain selection lines, the method further includes: applying, by the control circuit, a voltage to the second bit line to be lower than the voltage applied to the first bit line; and applying, by the control circuit, the voltage to the second bit line and the voltage to the first one of the plurality of first drain selection lines connected to a first one of the plurality of third drain selection switches during the first erase operation, so as to avoid generating GIDL current at the first one of the plurality of third drain selection switches. The second one of the first drain selection lines is connected to a second one of the plurality of third drain selection switches, and the first one of the plurality of third drain selection switches is located closer to the second bit line than the second one of the plurality of third drain selection switches.

In an embodiment, where the cell array further comprises a fourth NAND string comprising a plurality of fourth flash memory cells whose control gates are connected to the plurality of word lines, and a plurality of fourth drain selection switches connected between the plurality of fourth flash memory cells and the second bit line and controlled by the plurality of second drain selection lines, the method further includes applying, by the control circuit, the voltage to the second bit line and the voltage to the first one of the plurality of second drain selection lines connected to a first one of the plurality of fourth drain selection switches during the first erase operation, so as to avoid generating GIDL current at the first one of the plurality of fourth drain selection switches. The second one of the second drain selection lines is connected to a second one of the plurality of fourth drain selection switches, and the first one of the plurality of fourth drain selection switches is located closer to the second bit line than the second one of the plurality of fourth drain selection switches.

In an embodiment, a difference between the voltage applied to the first one and the second one of the plurality of first drain selection lines is sufficient to generate GIDL current at the second one of the plurality of first drain selection switches and avoid generating GIDL current at the second one of the plurality of third drain selection switches.

Although some embodiments have been described above for illustrative purposes, various changes and modifications may be made to the above-described embodiments.

What is claimed is:

1. A flash memory device comprising:
a cell array including a first NAND string comprising a plurality of first flash memory cells whose control gates are connected to a plurality of word lines, and a plurality of first drain selection switches connected between the plurality of first flash memory cells and a first bit line and controlled by a plurality of first drain selection lines; and
a control circuit configured to control a first erase operation for erasing a selected first flash memory cell among the plurality of first flash memory cells,
wherein, during the first erase operation, the control circuit sets a voltage applied to the first bit line and a voltage applied to a first one of the plurality of first drain selection lines so as to generate GIDL current at a first one of the plurality of first drain selection switches,
wherein, during the first erase operation, the control circuit sets voltage applied to another one of the first drain selection lines other than the first one of the plurality of first drain selection lines, the voltage applied to the another one of the first drain selection lines being lower than the voltage applied to the first one of the plurality of first drain selection lines, and
wherein the first one of the plurality of first drain selection switches is connected to the first bit line, and the first one of the plurality of first drain selection lines controls the first one of the plurality of first drain selection switches.

2. The flash memory device of claim 1, wherein the cell array further comprises:
a second NAND string comprising a plurality of second flash memory cells whose control gates are connected to the plurality of word lines, and a plurality of second drain selection switches connected between the plurality of second flash memory cells and the first bit line and controlled by a plurality of second drain selection lines,
wherein, during the first erase operation, the control circuit sets the voltage applied to the first bit line and a voltage applied to a first one of the plurality of second drain selection lines so as to avoid generating GIDL current at a first one of the plurality of second drain selection switches,
wherein, during the first erase operation, the control circuit sets voltage applied to another one of the second drain selection lines other than the first one of the plurality of second drain selection lines, the voltage applied to the another one of the second drain selection lines being lower than the voltage applied to the first one of the plurality of second drain selection lines, and
wherein the first one of the plurality of second drain selection switches is connected to the first bit line, and the first one of the plurality of second drain selection lines controls the first one of the plurality of second drain selection switches.

3. The flash memory device of claim 2, wherein the cell array further comprises:
a third NAND string comprising a plurality of third flash memory cells whose control gates are connected to the plurality of word lines, and a plurality of third drain selection switches connected between the plurality of third flash memory cells and a second bit line and controlled by the plurality of first drain selection lines,
wherein, during the first erase operation, the control circuit controls a voltage applied to the second bit line to be lower than the voltage applied to the first bit line,
wherein, during the first erase operation, the control circuit sets the voltage applied to the second bit line and the voltage applied to the first one of the plurality of first drain selection lines so as to avoid generating GIDL current at a first one of the plurality of third drain selection switches, and
wherein the first one of the plurality of third drain selection switches is connected to the second bit line, and the first one of the plurality of first drain selection lines controls the first one of the plurality of third drain selection switches.

4. The flash memory device of claim 3, wherein the cell array further comprises:
a fourth NAND string comprising a plurality of fourth flash memory cells whose control gates are connected to the plurality of word lines, and a plurality of fourth drain selection switches connected between the plurality of fourth flash memory cells and the second bit line and controlled by the plurality of second drain selection lines,
wherein, during the first erase operation, the control circuit sets the voltage applied to the second bit line and the voltage applied to the first one of the plurality of second drain selection lines so as to avoid generating GIDL current at a first one of the plurality of fourth drain selection switches, and
wherein the first one of the plurality of fourth drain selection switches is connected to the second bit line, and the first one of the plurality of second drain selection lines controls the first one of the plurality of fourth drain selection switches.

5. The flash memory device of claim 4, wherein the first NAND string further comprises a plurality of first source selection switches configured to connect the plurality of first flash memory cells to a source line under control of a plurality of source selection lines,
wherein the second NAND string further comprises a plurality of second source selection switches configured to connect the plurality of second flash memory cells to the source line under control of the plurality of source selection lines,
wherein the third NAND string further comprises a plurality of third source selection switches configured to connect the plurality of third flash memory cells to the source line under control of the plurality of source selection lines, and
wherein the fourth NAND string further comprises a plurality of fourth source selection switches configured to connect the plurality of fourth flash memory cells to the source line under control of the plurality of source selection lines.

6. The flash memory device of claim 5, wherein, during the first erase operation, the control circuit sets a voltage applied to the source line to be equal to the voltage applied to the first bit line.

7. The flash memory device of claim 5, wherein, during the first erase operation, the control circuit sets a voltage applied to a first one of the plurality of source selection lines to be equal to the voltage applied to the first one of the plurality of second drain selection lines, and
wherein the first one of the plurality of source selection lines controls a first one of the plurality of first source selection switches that is connected to the source line.

8. The flash memory device of claim 7, wherein, during the first erase operation, the control circuit sets voltage applied to another one of the source selection lines other than the first one of the plurality of source selection lines, the voltage applied to the another one of the source selection lines being lower than the voltage applied to the first one of the plurality of source selection lines.

9. The flash memory device of claim 5, wherein, during a block erase operation, the control circuit sets a voltage applied to a first one of the plurality of source selection lines to be equal to the voltage applied to the first one of the plurality of first drain selection lines during the first erase operation,
wherein the first one of the plurality of source selection lines controls a first one of the plurality of first source selection switches connected to the source line, and
wherein, during the block erase operation, the control circuit sets voltage applied to another one of the plurality of source selection lines other than the first one of the plurality of source selection lines, the voltage applied to the another one of the plurality of source selection lines being lower than the voltage of the first one of the plurality of source selection lines.

10. The flash memory device of claim 1, wherein the plurality of first drain selection switches comprise a plurality of NMOS transistors connected in series, and gate voltages applied to the plurality of NMOS transistors during the first erase operation decrease in a direction from the first bit line toward the plurality of first flash memory cells.

11. The flash memory device of claim 1, wherein, during the first erase operation, the control circuit sets a control gate voltage of the selected first flash memory cell to be different from control gate voltage of another one of the first flash memory cells other than the selected first flash memory cell.

12. A method of operating a flash memory device, wherein the flash memory device comprises a cell array and a control circuit, the cell array including a first NAND string comprising a plurality of first flash memory cells whose control gates are connected to a plurality of word lines, and a plurality of first drain selection switches connected between the plurality of first flash memory cells and a first bit line and controlled by a plurality of first drain selection lines, the method comprising:
applying, by the control circuit, a voltage to the first bit line and a voltage to a first one the plurality of first drain selection lines connected to a first one of the plurality of first drain selection switches, so as to generate GIDL current at the first one of the plurality of first drain selection switches during a first erase operation, the first erase operation performed on a selected flash memory cell among the plurality of first memory cells; and
applying, by the control circuit, a voltage to a second one of the first drain selection lines connected to a second one of the plurality of first drain selection switches during the first erase operation, the voltage applied to the second one of the first drain selection lines being lower than the voltage applied to the first one of the plurality of first drain selection lines,
wherein the first one of the plurality of first drain selection switches is located closer to the first bit line than the second one of the plurality of first drain selection switches.

13. The method of claim 12, wherein the cell array further comprises a second NAND string comprising a plurality of second flash memory cells whose control gates are connected to the plurality of word lines, and a plurality of second drain selection switches connected between the plurality of second flash memory cells and the first bit line and controlled by a plurality of second drain selection lines, the method further comprising:
applying, by the control circuit, the voltage to the first bit line and a voltage to a first one of the plurality of second drain selection lines connected to a first one of the plurality of second drain selection switches during the first erase operation, so as to avoid generating GIDL current at the first one of the plurality of second drain selection switches; and
applying, by the control circuit, a voltage to a second one of the second drain selection lines connected to a second one of the plurality of second drain selection switches during the first erase operation, the voltage applied to the second one of the second drain selection lines being lower than the voltage applied to the first one of the plurality of second drain selection lines,
wherein the first one of the plurality of second drain selection switches is located closer to the first bit line than the second one of the plurality of second drain selection switches.

14. The method of claim 13, wherein the cell array further comprises a third NAND string comprising a plurality of third flash memory cells whose control gates are connected to the plurality of word lines, and a plurality of third drain selection switches connected between the plurality of third flash memory cells and a second bit line and controlled by the plurality of first drain selection lines, the method further comprising:
applying, by the control circuit, a voltage to the second bit line to be lower than the voltage applied to the first bit line; and
applying, by the control circuit, the voltage to the second bit line and the voltage to the first one of the plurality of first drain selection lines connected to a first one of the plurality of third drain selection switches during the first erase operation, so as to avoid generating GIDL current at the first one of the plurality of third drain selection switches,
wherein the second one of the first drain selection lines is connected to a second one of the plurality of third drain selection switches, and the first one of the plurality of third drain selection switches is located closer to the second bit line than the second one of the plurality of third drain selection switches.

15. The method of claim 14, wherein the cell array further comprises a fourth NAND string comprising a plurality of fourth flash memory cells whose control gates are connected to the plurality of word lines, and a plurality of fourth drain selection switches connected between the plurality of fourth flash memory cells and the second bit line and controlled by the plurality of second drain selection lines, the method further comprising:
applying, by the control circuit, the voltage to the second bit line and the voltage to the first one of the plurality of second drain selection lines connected to a first one of the plurality of fourth drain selection switches during the first erase operation, so as to avoid generating GIDL current at the first one of the plurality of fourth drain selection switches,
wherein the second one of the second drain selection lines is connected to a second one of the plurality of fourth drain selection switches, and the first one of the plurality of fourth drain selection switches is located closer to the second bit line than the second one of the plurality of fourth drain selection switches.

16. The method of claim 14, wherein a difference between the voltage applied to the first one and the second one of the plurality of first drain selection lines is sufficient to generate GIDL current at the second one of the plurality of first drain selection switches and avoid generating GIDL current at the second one of the plurality of third drain selection switches.
